(19) United States
(12) Patent Application Publication
(10) Pub. No.: US 2003/0106644 A1
(43) Pub. Date: Jun. 12, 2003

(54) Electrode apparatus and method for plasma processing

(76) Inventors: Murray D. Sirkis, Tempe, AZ (US); Wayne L. Johnson, Phoenix, AZ (US); Steven T. Fink, Mesa, AZ (US)

Correspondence Address: PILLSBURY WINTHROP, LLP, P.O. BOX 10500, MCLEAN, VA, 22102, US

(21) Appl. No.: 10/345,232

(22) Filed: Jan. 16, 2003

Related U.S. Application Data
(63) Continuation of application No. PCT/US01/22510, filed on Jul. 19, 2001.

(51) Int. Cl. H01L 21/3065; C23C 16/00

(52) U.S. Cl. 156/345.48; 118/723 E; 156/345.43

(57) ABSTRACT

A plasma processing system includes an electrode assembly (150) having a metal drive electrode (154) coupled to a source electrode (152) using fasteners (132) which do not introduce contaminants into the plasma processing chamber. In addition, the source electrode (152) is provided with at least a partially metallized surface (151) that serves as the interface between the metal drive electrode (154) and the source electrode material (153).

### CROSS REFERENCE TO RELATED CO-PENDING APPLICATIONS

This a Continuation of International Application No. PCT/US01/22510, which was filed on Jul. 19, 2001 and claims priority from Provisional U.S. Application No. 60/219,453, which was filed Jul. 20, 2000. This application is also related to Provisional U.S. application Ser. No. 60/219,713, filed Jul. 20, 2000 and entitled IMPROVED ELECTRODE FOR PLASMA PROCESSING SYSTEM, the contents of which are expressly incorporated herein by reference.

### BACKGROUND OF THE INVENTION

The present invention relates to the field of plasma processing of silicon wafers and more particularly to an improved electrode assembly for use in plasma processing equipment.

As is known in the art, a fundamental step in the manufacturing of semiconductor devices, such as integrated circuits (ICs), is the process of forming electrical interconnections. The formation of electrical circuits, such as those containing semiconductor transistors, involves a series of steps starting with the formation of a silicon wafer. The blank silicon wafer is then processed using successive steps of depositing and etching away various materials to form the proper interconnections and therefore the electrical circuits.

Such depositing and etching operations may be carried out in a plasma reactor system. In semiconductor manufacturing, plasma reactor systems are used to remove material from or deposit material on a workpiece (e.g. semiconductor substrate) in the process of making IC devices. A key factor in obtaining the highest yield and overall quality of ICs is the uniformity of the etching and deposition process.

There are several different kinds of plasma processes used during wafer processing. These processes include: (1) plasma etching, (2) plasma deposition, (3) plasma assisted photo resist stripping and (4) in situ plasma chamber cleaning. Each of these plasma processes has associated plasma density non-uniformities due to the generation of harmonics of the plasma excitation frequency. These non-uniform plasmas erode the silicon electrode (used as a source electrode in plasma processing) non-uniformly. The non-uniformly etched silicon electrode in turn exacerbates the non-uniformity of the plasma. To ensure uniform plasmas, these silicon electrodes are changed frequently. If a system with a non-uniform plasma is used for semiconductor wafer processing, the non-uniform plasma can produce non-uniform etching or deposition on the surface of the semiconductor wafers. Thus, the control of uniform etching of the silicon electrode directly affects the quality of integrated circuits manufactured by the semiconductor industry.

When it is desired to deposit materials onto a target semiconductor wafer, a plasma reactor is sometimes used to sputter a variety of materials, one of which may be silicon, onto the wafer. In these sputtering applications, a silicon disk, silicon dioxide disk or doped-silicon disk is used as a facing on a metal drive electrode to provide a source of material to be deposited on a surface of the semiconductor wafer to form a variety of circuit patterns. The silicon disk may be referred to as a source electrode.

A problem that has plagued prior art plasma reactors is the control of the plasma to obtain uniform workpiece etching and deposition. In plasma reactors, the degree of etch or deposition uniformity is determined by the uniformity of the plasma density profile. The latter is dictated by the design of the overall system, and in particular the design of the electrode assembly used to create the plasma in the interior region of the reactor chamber.

As illustrated in FIG. 1, a typical plasma reactor system 10 is shown to include, inter alia, a plasma chamber 11 in which a silicon wafer 18 is processed. Silicon wafer 18 is placed on a chuck 16 and exposed to various plasmas depending on whether the wafer is undergoing an etch or deposition step. The plasma within chamber 11 is formed by electromechanically coupling a silicon electrode 14 to a metal drive electrode 12 and driving an RF signal through metal electrode 12 and consequently through silicon electrode 14. Silicon electrode 14, in effect, becomes the plasma source electrode. The plasma formed within chamber 11 depends upon a variety of factors including the RF power magnitude, the gas used to fill chamber 11, and the composition of source electrode 14. During processing of silicon wafers, a silicon disk may be used as electrode 14 and is consumed during the process and therefore must be changed periodically in order to maintain consistent processing conditions with plasma chamber 11.

In prior art systems such as system 10 of FIG. 1, silicon electrode 14 is typically attached to metal drive electrode 12 by means of metal screws 23. Metal screws 23 pass through clearance holes in silicon electrode 14 and mate with threaded holes in metal drive electrode 12 or mate with metal nuts 25 on the back side of metal drive electrode 12. The clearance holes in the silicon electrode are countersunk to assure that the heads of metal screws 23 do not protrude beyond the face of source electrode 14 that is exposed to chamber 11. Due to the electrical, thermal and physical contact requirements between silicon electrode 14 and metal drive electrode 12, there is a need to ensure a proper connection between the two.

To achieve proper contact between silicon electrode 14 and metal drive electrode 12, metal screws 23 for the silicon electrode are tightened to a specified torque in the range of 1.1 to 3.5 in-lb. Even when screws 23 are tightened to an acceptable torque rating, the electromechanical contact is generally poor and unrepeatable. This poor contact results in plasma process variation each time silicon electrode 14 is replaced.

In addition, the exposed heads of countersunk screws 23 can introduce contaminants into the plasma. To alleviate this contamination problem, a quartz shield ring 24 is provided to cover the recessed heads of metal screws 23 to shield them from the plasma formed during processing. Quartz ring 24 typically includes at least three threaded holes configured to accept metal screws (not shown) that mate with conical recesses on the cylindrical surface of the metal electrode. To avoid damage to quartz shield 24 due to excess stress, these screws are inserted only as far as required to keep the shield in place. Although quartz shield ring 24 prevents contamination due to metal screws 23, the quartz ring may introduce its own undesirable impurities into the chamber during formation of plasma.

It would be advantageous therefore to provide an apparatus for plasma processing of semiconductor wafers that allows for secure, repeatable attachment of a silicon electrode to a metal drive electrode while at the same time eliminating the possibility of contamination from an associated attachment and shield mechanism.

### BRIEF SUMMARY OF THE INVENTION

The present invention provides an electrode assembly that may be used in plasma processing equipment typically used in the formation of integrated circuits on silicon wafers. The electrode assembly includes a metal drive electrode adapted to be coupled to a source of RF energy and is typically located within a plasma chamber. Coupled to the metal drive electrode is a source electrode that is typically consumed during the formation of plasma within the chamber. Since the source electrode is consumed during plasma processing, it is fastened to the metal drive electrode with a removable fastening system. The fastening system includes at least one mating part having no metallic content. This non-metallic part of the fastening system may be made of a material such as polytetraflouroethylene (PTFE). The non-metallic part of the fastening system may be exposed in the reactor chamber since it introduces no contaminants during the formation of plasma. The other mating part of the fastening system may be a bolt or similar fastener made of metal or non-metallic materials as it is not exposed to the reactor chamber. With such an arrangement, the need for a quartz shield ring is eliminated with the resulting electrode assembly producing no contaminants during plasma processing.

The present invention also provides a source electrode having an improved electromechanical interface between the source electrode and the metal drive electrode. The improved interface is generated by depositing a layer of metal on the face of the source electrode that is in contact with the drive electrode. The metal layer may cover all or a portion of the surface of the source electrode. Additionally, multiple metal layers including a first non-diffusive metal such as nickel followed by a soft metal such as indium may be employed to control the drive electrode/source electrode interface.

The present invention also provides the combination of the non-metallic fastening system with a source electrode having at least one layer of metal deposited on the surface. Providing a source electrode with a metal interface layer allows for a reduction in the force required to maintain a proper contact between the source electrode and the drive electrode. Consequently, the fastening system may be designed to exert reduced forces. In the case of a threaded fastening system, a reduction in thread force loading is achieved. As a result, a non-metallic bolt material such as silicon may be used in combination with the (PTFE) mating portion. This arrangement completely eliminates metal from the electrode fastening system.

### BRIEF DESCRIPTION OF THE SEVERAL VIEWS OF THE DRAWING

The above described and other features of the present invention will be described while referring to the accompanying drawings in which:

FIG. 1 is a diagrammatic elevational representation of a prior art plasma deposition and etching system;

FIG. 2 is a diagrammatic elevational representation of a preferred embodiment of a plasma deposition and etching system according to the present invention;

FIG. 2A is a bottom plan view of the source electrode of the plasma deposition and etching system of FIG. 2;

FIG. 3 is a top plan view of one embodiment of the source electrode of the plasma deposition and etching system of FIG. 2;

FIG. 4 is a top plan view of an alternate embodiment of the source electrode of the plasma deposition and etching system of FIG. 2;

FIG. 5 is an elevational view of an alternative metal layer structure of the source electrode of the plasma deposition and etching system of FIG. 2;

FIG. 6 is an elevational view of a second alternative metal layer structure of the source electrode of the plasma deposition and etching system of FIG. 2;

FIG. 7 is an elevational view of a third alternative metal layer structure of the source electrode of the plasma deposition and etching system of FIG. 2;

FIG. 8 is a side elevational view of a second embodiment of a component of the system shown in FIG. 2;

FIGS. 9A, 9B and 9C are cross-sectional views along planes A-A, B-B and C-C of FIG. 8;

FIG. 10 is a side elevational view of third embodiment of a component of the system shown in FIG. 2;

FIGS. 11A and 11B are cross-sectional views along planes A-A and B-B of FIG. 10; and

FIG. 12 is a side elevational view of fourth embodiment of a component of the system shown in FIG. 2.

### DETAILED DESCRIPTION OF THE INVENTION

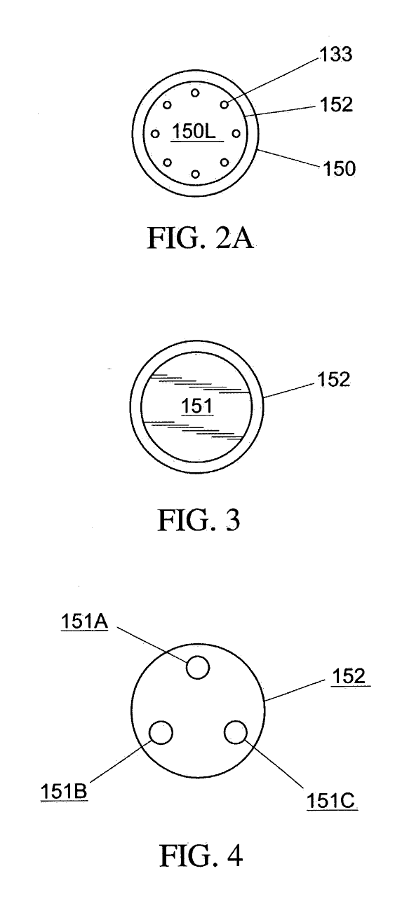

Referring now to FIG. 2, a plasma processing system 110 is shown to include, inter alia, a plasma chamber 120 that functions as a vacuum processing chamber adapted to perform plasma etching and deposition of a workpiece W. Here, workpiece W is a semiconductor wafer, such as silicon, and has an upper surface WS. Chamber 120 includes sidewalls 122, an upper wall 124 and a lower wall 126 that enclose an interior region 142 capable of supporting plasma 136. Chamber 120 further includes within region 142, a workpiece support 140 typically arranged adjacent lower wall 126 for supporting workpiece W while the workpiece is processed in chamber 120. As mentioned above, workpiece W can be a semiconductor substrate, such as silicon, on which patterns have been formed and where the patterns correspond to product devices (e.g. electronic circuits). Workpiece W can also be a semiconductor substrate that requires plasma cleaning, metal deposition or photoresist etching, etc.

Chamber 120 of system 110 includes an electrode assembly 150 arranged within, interior region 142 adjacent workpiece support 140. Electrode assembly 150 is preferably capacitively coupled to workpiece W when the workpiece is being plasma processed. Electrode assembly 150 includes an upper surface 150U facing away from workpiece support 140 and a lower surface 150L facing towards workpiece support 140. Electrode 150 serves to further divide plasma chamber interior region 142 into a first section 142U between chamber wall 124 and upper electrode surface 150U, and a second section 142L between lower electrode surface 150L and lower chamber wall 126. Preferably, sections 142U and 142L are totally isolated from one another by assembly 150. Plasma 136 is formed in second section 142L of interior region 142. Plasma 136 ideally has a plasma density (i.e., number of ions/volume, along with energy/ion) that is uniform, unless the density needs to be tailored to account for other sources of process non-uniformities. The density of plasma 136 has a density profile referred to herein as a “plasma density profile”.

As will be described in more detail below, electrode assembly 150 further includes a metal drive electrode 154 which has coupled thereto a source electrode 152 having an upper surface 152U and a lower surface 150L (note lower surface 150L of source electrode 152 serves as the lower surface for electrode assembly 150). Upper surface 152U is the contact surface between source electrode 152 and metal drive electrode 154. Source electrode 152 can include a metallization layer 151 on a surface of the silicon portion 153 of source electrode 152 thereby creating a metal-to-metal interface where drive electrode 154 meets source electrode 152.

Electrode assembly 150 can be electrically connected to a RF power supply system 162 which can have coupled thereto an associated match network MN to match the impedance of electrode assembly 150 and the associated excited plasma 136 to the source impedance of RF power supply system 162, thereby increasing the power that can be delivered by the RF power supply system 162 to the plasma electrode assembly 150 and the associated excited plasma 136. The plasma density of plasma 136 increases as the power delivered by RF power supply 160 to plasma 136 increases. Hence, for a given RF power supply system, the maximum attainable plasma density of plasma 136 is increased by means of the matching network. Moreover, workpiece holder 140 used to support wafer W can have a RF power supply 164 coupled thereto to bias the wafer W. A RF bias can be applied to wafer support 140 through a match network MN from RF generator 164.

Still referring to FIG. 2, plasma processing system 110 further includes a gas supply system 180 in pneumatic communication with plasma chamber 120 via one or more gas conduits 182 for supplying gas in a regulated manner to form plasma 136. Gas supply system 180 includes such gases as chlorine, hydrogen-bromide, octaflourocyclobutane, and various other fluorocarbon compounds, and for chemical vapor deposition applications includes silane, tungsten-tetrachloride, titanium-tetrachloride, and the like.

Plasma processing system 110 also includes a vacuum system 190 connected to chamber 120 for evacuating interior region section 142L to a desired pressure. The precise pressure depends on the nature of the plasma desired.

Plasma processing system 110 can further include a conventional workpiece handling and robotic system in operative communication with chamber 120 for transporting workpieces W to and from workpiece support 140. In addition, a cooling system 196 in fluid communication with electrode assembly 150 is preferably included for flowing a cooling fluid to and from the electrode.

Plasma processing system 12 can also include a main control system 200 to which RF power supply system 162, gas supply system 180, vacuum pump system, 190 and work piece handling and robotic system 194 are electronically connected. In the preferred embodiment, main control system 200 is a computer having a memory unit MU having both random access memory (RAM) and read-only memory (ROM), a central processing unit CPU, and a hard disk HD, all electronically connected. Hard disk HD serves as a secondary computer-readable storage medium, and can be, for example, a hard disk drive for storing information corresponding to instructions for controlling plasma system 110. Control system 200 also preferably includes a disk drive DD, electronically connected to hard disk HD, memory unit MU and central processing unit CPU, wherein the disk drive is capable of reading and/or writing to a computer-readable medium CRM, such as a floppy disk or compact disc (CD) on which is stored information corresponding to instructions for control system 200 to control the operation of plasma system 120.

It is also preferable that main control system 200 has data acquisition and control capability. A preferred control system 200 is a computer, such as a DELL PRECISION WORKSTATION 610™, available from Dell Computer Corporation, Dallas, Tex. As will be appreciated by those of skill in the art, data acquisition and control can be facilitated by coupling the electronic control systems associated with each of the subsystems 162, 164, 180, 190, 194, and 196 mentioned above via the workstation's included serial or parallel ports or can require additional hardware (not shown) coupled between main control system 200 and subsystems 162, 180, 190, 194 and 196. All components and systems 162-200 described above can be constructed and operated according to principles and techniques known in the art.

Electrode Assembly

According to the present invention, an electrode assembly is provided for use in a plasma processing system that allows a source electrode to be fastened to a drive electrode in a manner that eliminates plasma chamber contaminants. The elimination of contaminants is achieved by providing a novel fastening system that eliminates any exposed metal fasteners within the plasma chamber. The elimination of metallic fasteners in the plasma chamber further allows the elimination of the prior art quartz shield ring and its associated contribution of contaminants in the plasma chamber.

Referring again to FIG. 2, a preferred embodiment electrode assembly 150 will now be described. Source electrode 152 includes a portion 153, which is here made of silicon, and can further include a metal coating or layer 151 on the backside or upper surface of portion 153 of source electrode 152. Metal layer 151 then provides the upper surface 152U (i.e. contact surface) of source electrode 152. Metal layer 151 can be formed by any of a group of well-known physical deposition means, such as sputtering, evaporation or chemical vapor deposition. The metal chosen for metal layer 151 can be any one or combination of metals such as chromium, nickel, aluminum, indium or the like. As will be discussed in detail below, metal layer 151 can cover all or only a part of portion 153 and can include one or more layers of different materials.

As shown in FIG. 2, source electrode 152 can be coupled to metal drive electrode 151 with a plurality of threaded fasteners 130 inserted and coupled to mating insert sleeves 132. Here, insert sleeves 132 are preferably constructed of a non-reactive material such as PTFE and include a retaining portion 133 that is drawn against surface 150L of electrode assembly 150 in response to threading fasteners 130 into insert sleeves 132. Other materials such as Nylon, Vespel® or Delrin® can be used for insert sleeve 132 instead of PTFE. The material chosen should possess approximately the same properties in terms of strength and reactivity during plasma processing as PTFE. Insert sleeves 132 are preferably inserted through holes in source electrode 152 and corresponding holes in metal drive electrode 154.

As shown in FIG. 2A, the preferred embodiment of electrode assembly 150 includes a plurality of threaded inserts 132 (FIG. 2) spaced azimuthally about the proximate perimeter of source electrode 152 (where in FIG. 2A, only associated retaining portions 133 are visible). Here, eight inserts are shown with their associated retaining portions 133. However, additional or fewer bolt/fastener combinations can be employed depending on the particular system construction.

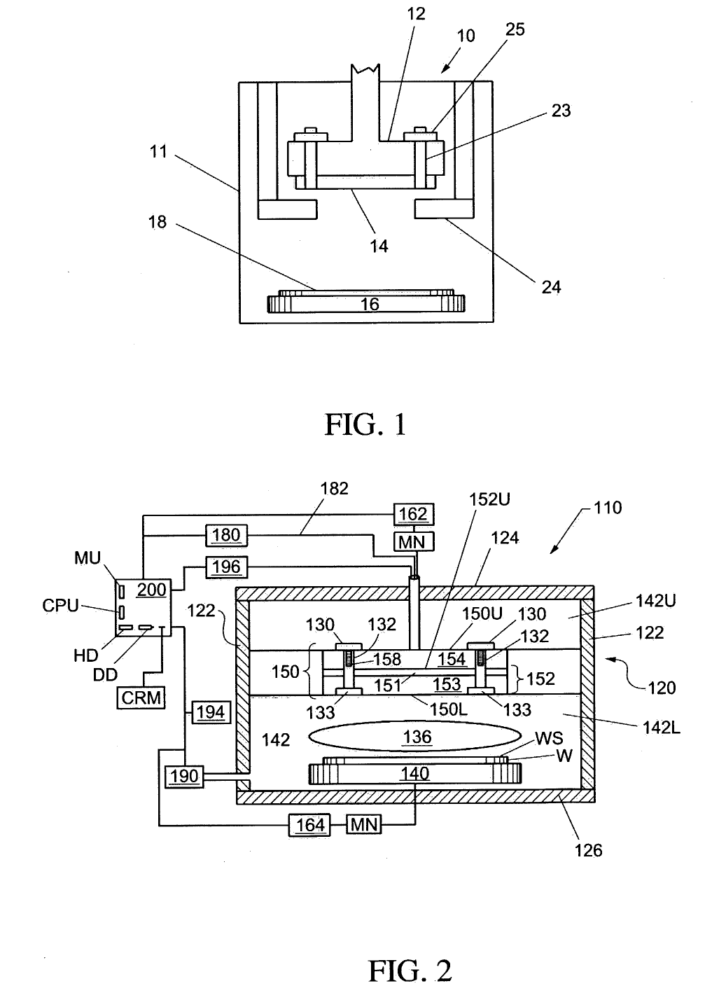

Insert sleeves 132 of the preferred embodiment play two important roles. Insert sleeves 132 expand laterally as threaded fasteners 130 are inserted into them and rotated to draw source electrode 152 into contact with metal drive electrode 154. Consequently, insert sleeves 132 resist rotating within their respective mounting holes as the torque applied to threaded fasteners 130 increases. In addition to their expansion capabilities, insert sleeves 132 are made of a non-reactive material, which eliminates contamination due to the prior art metal screws and the quartz shield ring described above in connection with FIG. 1. The use of insert sleeve 132 isolates threaded fasteners 130 completely from interior region 142L and thus eliminates the need for a quartz shield ring.

Alternatively, insert sleeves 132 could be provided with a square exterior section recessed into square holes in electrode assembly 150. In general, any convenient non-circular section and mating recess could be used. For such configurations, insert sleeves 132 need not be tapered.

As an alternative to the threaded fastener/insert sleeve combination described above, metal drive electrode 154 can be provided with threaded mounting holes in place of the smooth bore holes described above. Then, insert sleeves 132 can be replaced with bolts constructed of the same material as insert sleeves 132 (e.g. PTFE), while having the corresponding mating thread of the threaded mounting holes in metal drive electrode 154. With this arrangement, source electrode 152 can be secured to the metal drive electrode 154 by passing the threaded bolts through holes in the source electrode 152 and securing them to corresponding threaded holes in drive electrode 154. Tightening the bolts causes the associated bolt heads to bear against surface 150L of source electrode 152 and draw source electrode and metal drive electrode 154 together.

According to another aspect of the present invention, an electrode assembly for use in a plasma processing system is provided that includes a source electrode having at least a portion of one face covered with a layer of metal, one example of which has been described above. The metal layer is provided to ensure good electro-mechanical contact between the source electrode and the drive electrode.

In particular and referring now to FIG. 3, source electrode 152 is shown to include a metal layer 151 deposited on its upper surface (the surface that is intended to contact metal drive electrode 154 (FIG. 2)). Providing a metal layer on the upper surface of the source electrode serves multiple functions. It creates a surface that ensures a reliable and reproducible contact with metal drive electrode 154 every time a silicon electrode is replaced. This reproducible contact is particularly important for producing consistent chamber conditions for wafer processing. Metal layer 151 on the upper surface of source electrode 152 also serves to introduce a metal-to-metal contact between source electrode 152 and metal drive electrode 154 replacing the previous metal-to-semiconductor contact used in prior art systems (FIG. 1). This metal-to metal contact dramatically improves electrical, thermal and physical contacts between source electrode 152 and metal drive electrode 154. Furthermore, providing this metal-to-metal contact substantially reduces the force require to hold source electrode 152 in proper contact with metal drive electrode 154 and subsequently reduces the torque that is required to be applied to threaded fasteners 130 (FIG. 2).

A reduction in torque application to threaded fasteners 130 results in a concomitant reduction in loading forces on their associated threads. This thread force reduction makes possible the use of alternate materials for threaded fasteners 130. For example, threaded fasteners may be constructed of alternate materials such as silicon, quartz, plastic or some other non-metal material. Therefore, the metal screws and the potential contamination associated with them can be completely eliminated. A preferred arrangement includes a source electrode 152 having a metal layer 151 used in combination with insert sleeves 132 made of PTFE.

Referring now to FIG. 4, a second embodiment of source electrode 152 is shown. Here, rather than deposit a layer of metal 151 over the entire upper surface of source electrode 152, only portions or pads 151A-151C of metal are formed on source electrode 152. As will be apparent to those of skill in the art, pads 151A-151C can be formed by selectively etching away a metal layer, such as metal layer 151 (FIG. 2) discussed above, which has been deposited on the upper surface of source electrode 152. The pad configuration shown in FIG. 4 provides sufficient electrical, thermal and physical contacts for the plasma processing applications. If metal pads 151A-151C are made to cover three small areas, the physical contact between source electrode 152 and metal drive electrode 154 (FIG. 2) is improved substantially.

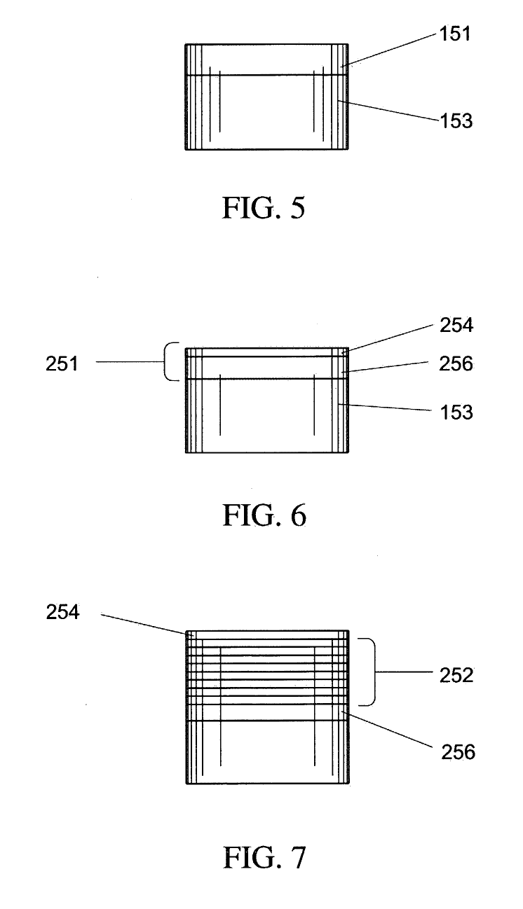

Referring now to FIG. 5, according to the first embodiment of source electrode 152, metal layer 151 can be made from a non-diffusive material such as nickel or tungsten. Utilizing a non-diffusive material for metal layer 151 minimizes undesirable interactions between the material (e.g. silicon) of portion 153 and metal layer 151. Alternatively and as shown in FIG. 6, a further embodiment of source electrode 152 includes a plurality of metal layers 251. Here, a layer 254 of soft metal is deposited on top of the non-diffusive metal layer 256. The use of a layer of soft metal provides good electrical, thermal and physical contacts between metallized source electrode 152 and metal drive electrode 154 (FIG. 2).

Yet another embodiment of source electrode 152 is shown in FIG. 7 to include a thick film 252 sandwiched between relatively thinner layer of non-diffusive metal 256 and soft metal 254. Thick film 252 includes a plurality of alternating layers of material, one of which is compressive in nature and the other tensile. Generally, the thin film of non-diffusive metal layer 256 is deposited first, and then two layers of tensile and compressive materials are deposited alternately to form a composite thick film 252. Finally, thin metal layer 254 of a soft metal such as indium is deposited on top of thick film 252, with the result that the composite film 252 is sandwiched between a metal layer 256 and metal layer 254. This configuration allows a much thicker metal layer 252-256 to be developed at the top of source electrode 152 should an application require it.

As regards the reference above to compressive and tensile layers, when a thin film or layer is deposited atop another film or layer, the film is said to be a compressive film when the stresses internal to the deposited film are negative such that the thin film is under compression, or is being compressed, and the film is said to be a tensile film when the stresses internal to the deposited thin film are positive such that the thin film is under tension, or is being stretched. The alternating layers of tensile and compressive films can be made of different materials or they can be preferably the same material. If they are the same material, the internal stresses they experience can depend upon the method used to deposit the thin film, i.e. electroplating, sputter deposition, chemical vapor deposition (CVD), plasma enhanced chemical vapor deposition (PECVD). For example, titanium films can be deposited under compression when PECVD is employed, whereas they can be deposited under tension when CVD is employed. Furthermore, there exists substantial literature dealing with the deposition of thin films, in particular, the measurement of internal stresses in thin films. For example, Thornton & Hoffman, in a paper entitled Internal stresses in titanium, nickel, molybdenum and tantalum films deposited by cylindrical magnetron sputtering, J. Vac. Sci. Technol., Vol. 14(1) (1977), present measurements of the internal stresses developed in thin films of titanium, nickel, tantalum and molybdenum sputter deposited onto a glass substrate in argon. They found that the argon pressure affected whether the film was under tension or compression. In particular, they showed that at low pressures (<0.20 Pa for Nickel), the film tended to be under compression and at higher pressures (>0.20 Pa for Nickel) it tended to be under tension. Other papers have shown that the stress is dependent upon the angle of deposition incidence (Hoffman & Thornton, J. Vac. Sci. Technol., Vol. 16(2), (1979)) and discharge voltage. Hoffman & Gaerttner (J. Vac. Sci. Technol., Vol. 17(1), (1980)) present the effect of ion bombardment on the deposition of thermally evaporated chromium films. The film stress is therefore dependent upon a wide range of parameters, the film material, the substrate material, the method of deposition, which further includes the process parameters (i.e. pressure, chemistry, plasma, etc.), and the temperature. The specific design of such a stack can use that information presented in the archival literature as well as employ the techniques presented in the literature to design new film stacks. Lastly, a typical stack of alternating films can comprise a total of ten film layers, each of which is approximately 0.1 μm thick, therefore leading to a 1 μm thick film stack, with all films in the stack preferably being made of the same material.

In general the thickness of metal layer 151 on the upper surface of source electrode 152 is determined by the amount of total current the electrode needs to carry. The amount of total current carried in these metal layers is generally on the order of several amperes. Also, the conductance throughout the metal layer should be significantly greater than the conductance along the surface of the silicon. This tends to promote current flow within the metal layer or along the surface of the metal layer and reduce the current flow crossing from the metal layer into the silicon or along the surface of the silicon. However, care must be taken to ensure that metal layer 151 is not so thick as to cause source electrode 152 to bow.

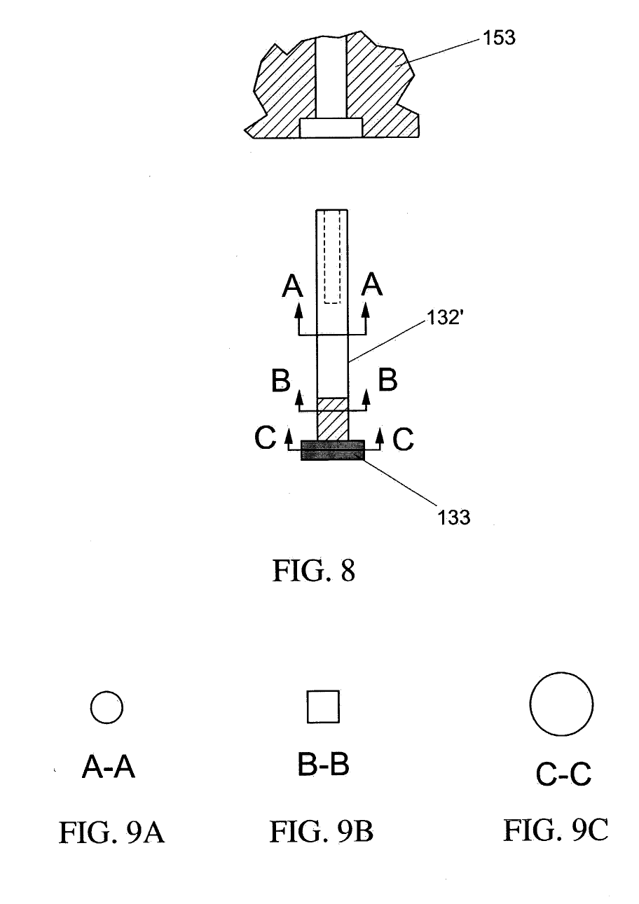

FIG. 8 is a side elevational view of another embodiment of a sleeve 132′ for insertion into holes in electrodes 152 and 154, and FIGS. 9A, 9B and 9C are cross-sectional views taken along planes A-A, B-B and C-C, respectively, of FIG. 8. Sleeve 132′ is composed of three sections, each of which has the cross section shown in a respective one of FIGS. 9A, 9B and 9C. Cross-section A-A of the sleeve can be circular, while near the head or cap of the sleeve, cross-section B-B is non-circular. Of course, the holes through which sleeve 132′ passes must be machined to have the same cross-sections. The non-circular cross-section B-B will prevent sleeve 132′ from rotating within the holes through which it is inserted. Retaining portion 133 of sleeve 132′ can have a circular cross-section C-C, as shown.

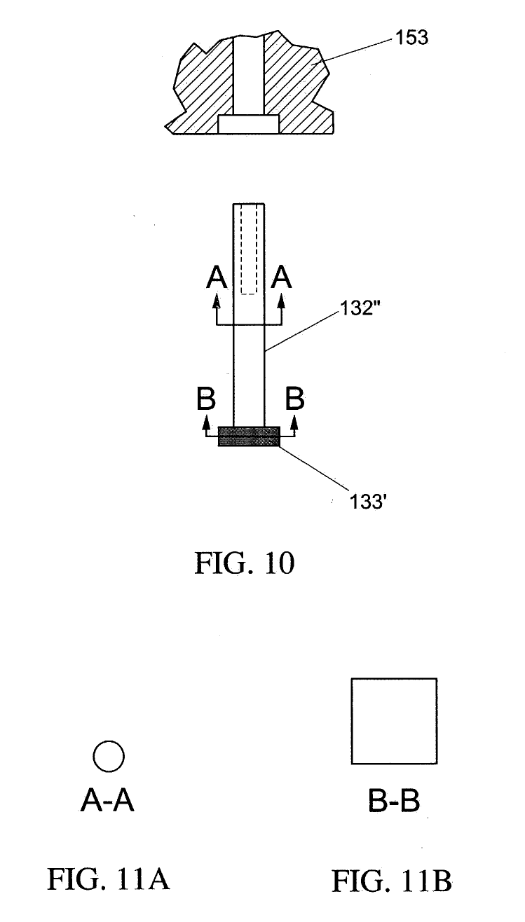

FIG. 10 is a side elevational view of another embodiment of a sleeve 132″ for insertion into holes in electrodes 152 and 154, and FIGS. 11A and 11B are cross-sectional views taken along planes A-A and B-B, respectively, of FIG. 10. or a non-circular as shown in figure B. In this embodiment, the entirety of sleeve 132″ has a circular cross section, as shown in FIG. 11A, except for retaining portion 133′, which has a non-circular cross section, as shown in FIG. 11B. As in the case of the embodiment of FIGS. 8 and 9A-C, the holes through which sleeve 132″ passes must be machined to have the same cross-sections and the non-circular cross-section B-B will prevent sleeve 132″ from rotating within the holes through which it is inserted.

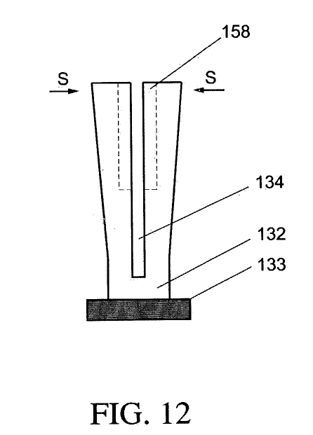

Referring now to FIG. 12, according to the preferred embodiment, each insert sleeve 132 can be tapered on the outer diameter and along its longitudinal axis. Specifically, sleeve 132 can have a tapered outer diameter along its longitudinal axis, wherein the outer diameter increases from the bottom, adjacent retaining portion 133, to the top, adjacent fastener 130. Two diametrically opposite slits 134 can be formed in sleeve 132 to extend in a direction along its longitudinal axis. For insertion into associated holes in electrodes 152 and 154, sleeve 132 can be depressed radially inwardly, or squeezed, in the direction of arrows S. Slits 134 can extend along the length of the internally threaded section 158 of sleeve 132 or they can extend further along the sleeve if the slit or cut extends through the centerline of the sleeve. Once sleeve 132 is inserted, radially outward expansion of the sleeve will hold it in place by means of friction, i.e. sleeve 132 will not fall out of the hole when threaded fastener 130 is inserted into internally threaded section 158 of sleeve 132.

Although the above described electrode assembly has been described in connection with a plasma reactor, it should be understood that the present invention can be employed in any system where a drive electrode is coupled to a source electrode. The many features and advantages of the present invention are apparent from the detailed specification, and, thus, it is intended by the appended claims to cover all such features and advantages of the described apparatus that follow the true spirit and scope of the invention. Furthermore, since numerous modifications and changes will readily occur to those of skill in the art, it is not desired to limit the invention to the exact construction and operation described herein. Moreover, the process and apparatus of the present invention, like related apparatus and processes used in the semiconductor arts tend to be complex in nature and are often best practiced by empirically determining the appropriate values of the operating parameters or by conducting computer simulations to arrive at a best design for a given application. Accordingly, all suitable modifications and equivalents should be considered as falling within the spirit and scope of the invention.

What is claimed is:

1. An electrode assembly comprising:
a metal drive electrode adapted to be coupled to a source of RF energy;
a source electrode removably coupled to said drive electrode; and
at least one fastener constructed at least partially of a non-metallic material and coupling said source electrode to said metal drive electrode.

2. The electrode assembly of claim 1 wherein said a least one fastener comprises:
a longitudinally elongated member having a longitudinal axis and first and second ends;
a cap having a generally planar first face disposed on said first end such that said first face is generally perpendicular to the longitudinal axis of said member, said member having a threaded bore extending from an opening in said second end and extending towards said first end; and
a bolt having threads configured to mate with corresponding threads of said threaded bore.

3. The electrode assembly of claim 2 wherein said elongated member is generally tapered in an outward direction beginning near said first end and extending toward said second end.

4. The electrode assembly of claim 2 wherein said drive electrode includes a first generally planar face with at least one mounting hole disposed therethrough and said source electrode includes a corresponding generally planar face with at least one mounting hole disposed therethrough and wherein said drive electrode and source electrode are arranged face to face such that each of said respective mounting holes are in substantial alignment and wherein said elongated member extends through each of said mounting holes.

5. The electrode assembly of claim 4 wherein said elongated member has a substantially non-circular cross section along at least part of its length and wherein said mounting hole of said metal drive electrode has a corresponding non-circular bore therethrough, such that when said elongate member is disposed within said non-circular bore, rotation of said elongated member is prevented.

6. The electrode assembly of claim 4 wherein said cap has a substantially non-circular cross section and said mounting hole source electrode includes a corresponding non-circular recess and wherein said cap is disposed within said recess.

7. The electrode assembly of claim 3 wherein said elongated member is made from polytetraflouroethylene and said bolt is constructed of a metallic material.

8. The electrode assembly of claim 3 wherein said elongated member is made from polytetraflouroethylene and said bolt is constructed of a non-metallic material.

9. The electrode assembly of claim 1 wherein said source electrode further comprises:
a disc of semiconductor material and a layer of metal disposed on a first face of said disc; and
wherein said electrode assembly is arranged such that the layer of metal on said first face of said disc is in contact with a first face of said metal electrode.

10. The electrode assembly according to claim 9 wherein said metal is nickel or aluminum.

11. The electrode assembly according to claim 9 further comprising a second metal layer disposed on said metal layer and being made from a non-diffusive material.

12. The electrode assembly of claim 11 further comprising alternating layers of compressive and tensile materials are disposed between said metal layer and said second metal layer.

13. A plasma processing system comprising:
a vacuum chamber;
an RF power supply;
an electrode assembly disposed within said vacuum chamber and being further composed of:
a metal drive electrode adapted to be coupled to a source of RF energy;
a source electrode removably coupled to said drive electrode; and
at least one fastener constructed at least partially of a non-metallic material coupling said source electrode to said drive electrode.

14. The plasma processing system of claim 13 wherein said fastener comprises:
a longitudinally elongated member having first and second ends;
a cap having a generally planar first face disposed on said first end such that said first face is generally perpendicular to the longitudinal axis of said member, said member having a threaded bore extending from an opening in said second end toward said first end; and
a bolt having threads configured to mate with corresponding threads of said threaded bore.

15. The plasma processing system of claim 13 wherein said drive electrode includes a first generally planar face with at least one mounting hole extending through said drive electrode, and said source electrode includes a corresponding generally planar face with at least one mounting hole extending through said source electrode and wherein said drive electrode and source electrode are arranged face to face such that said respective mounting holes are in substantial alignment with one another and wherein said longitudinal member extends through each of said mounting holes.

16. The plasma processing system of claim 14 wherein said elongated member is generally tapered in an outward direction beginning near said first end and extending toward said second end.

17. The plasma processing system of claim 15 wherein said elongated member has a substantially non-circular cross section along at least part of its length and wherein said mounting hole of said metal drive electrode has a corresponding non-circular bore therethrough, such that when said elongate member is disposed within said non-circular bore, rotation of said elongated member is prevented.

18. The plasma processing system of claim 15 wherein said cap has a substantially non-circular cross section and said mounting hole source electrode includes a corresponding non-circular recess and wherein said cap is disposed within said recess.

19. The plasma processing system of claim 1 wherein said elongated member is made from polytetraflouroethylene and said bolt is constructed of a metallic material.

20. The plasma processing system of claim 13 wherein said elongated member is made from polytetraflouroethylene and said bolt is constructed of a non-metallic material.

21. The plasma processing system of claim 13 wherein said source electrode further comprises:
a disc of semiconductor material and a layer of metal disposed on a first face of said disc; and
wherein said electrode assembly is arranged such that the layer of metal on said first face of said disc is in contact with said metal electrode.

22. The plasma processing system of claim 21 wherein said metal is nickel or aluminum.

23. The plasma processing system of claim 21 further comprising a second metal layer disposed on said metal layer and being made from a non-diffusive material.

24. The plasma processing system of claim 23 further comprising alternating layers of compressive and tensile materials disposed between said metal layer and said second metal layer.

25. A source electrode for attachment to a metal drive electrode in a plasma processing system, said source electrode comprising:
a disc of semiconductor material; and
a layer of metal disposed on a first face of said disc.

26. The source electrode according to claim 25 wherein said metal is nickel or aluminum.

27. The source electrode of claim 25 further comprising a second metal layer disposed on said metal layer and being made from a non-diffusive material.

28. The source electrode according to claim 27 further comprising alternating layers of compressive and tensile materials disposed between said metal layer and said second metal layer.

29. The source electrode according to claim 25 wherein said semiconductor material is silicon.

30. The source electrode according to claim 25 wherein said metal layer covers the entire first face of said disc.

31. The source electrode according to claim 25 wherein said metal layer covers only a portion of said first face of said disc.

32. A method of operating a plasma processing system including the steps of:
providing a source electrode configured for coupling to a drive electrode;
depositing a metal layer on one face of said source electrode; and
fastening said source electrode to said drive electrode such that said metal layer is in contact with said drive electrode.

33. The method of claim 32 wherein the fastening step includes the steps of: providing at least partially non-metallic fasteners; and mounting said fasteners to said source electrode and said drive electrode such that no metal portion of said fasteners is exposed to a reactor chamber of said plasma processing system.
